(19) United States
(12) Patent Application Publication
(10) Pub. No.: US 2026/0172009 A1
(43) Pub. Date: Jun. 18, 2026

(54) THROTTLER BASED MITIGATOR

(71) Applicant: Arm Limited, Cambridge (GB)

(72) Inventors: Ekaterina BEREZINA, Cambridge (GB); Amit CHHABRA, Noida (IN); Rui Pedro GASPAR PINHEIRO, Cambridge (GB); Sarah Jean KIMBER, Sheffield (GB); Mahadevamurty NEMANI, San Diego, CA (US)

(21) Appl. No.: 18/982,322

(22) Filed: Dec. 16, 2024

(51) Int. Cl. H03K 5/01; G06F 1/10; G06F 1/12

(52) U.S. Cl. CPC H03K 5/01; G06F 1/10; G06F 1/12

(57) ABSTRACT

A throttler based mitigator including circuitry, related methods and state machine, the circuitry including: a first component to: receive a target index corresponding to a target level of throttle for a clock output signal at the clock throttle circuit; determine a current index implemented at the clock throttle circuit, where the current index corresponds to a current level of throttle of the clock output signal; provide, responsive to the determination, an index signal to cause the clock throttle circuit to throttle the clock output signal in accordance with the index signal.

### TECHNICAL FIELD

The present techniques relate to a throttler based mitigator. In particular, the present techniques relate to circuitry, related methods and state machine therefor.

### BACKGROUND

Some computer units (e.g. a central processor unit (CPU) or graphics processor unit (GPU)) may experience performance issues due to, for example overcurrent event(s) or overtemperature events(s).

There is a need for mitigation action to address such performance issues.

### SUMMARY

The present techniques relate to addressing or mitigating such performance issues or improving known mitigation techniques.

According to a first aspect, there is provided circuitry for controlling a clock throttle circuit, the circuitry comprising: a first component to: receive a target index corresponding to a target level of throttle for a clock output signal at the clock throttle circuit; determine a current index implemented at the clock throttle circuit, where the current index corresponds to a current level of throttle of the clock output signal; provide, responsive to the determination, an index signal to cause the clock throttle circuit to throttle the clock output signal in accordance with the index signal.

According to a further aspect there is provided a method for controlling a clock throttle circuit, the method performed by circuitry, the method comprising: receiving a target index corresponding to a target level of throttle for a clock output signal at the clock throttle circuit; determining a current index implemented at the clock throttle circuit, where the current index corresponds to a current level of throttle of the clock output signal; providing, responsive to the determination, an index signal to cause the clock throttle circuit to throttle the clock output signal in accordance with the index signal.

According to a further aspect, there is provided a non-transitory computer readable storage medium comprising code which when implemented on a processor causes the processor to carry out the method of the previous aspect.

According to a further aspect there is provided a state machine for controlling a clock throttle circuit, the state machine configured to: receive a target index corresponding to a target level of throttle for a clock output signal at the clock throttle circuit; determine a current index implemented at the clock throttle circuit, where the current index corresponds to a current level of throttle of the clock output signal; provide, responsive to the determination, an index signal to cause the clock throttle circuit to throttle the clock output signal in accordance with the index signal.

According to a further aspect, there is provided a system comprising: the above circuitry, implemented in at least one packaged chip; at least one system component; and a board, wherein the at least one packaged chip and the at least one system component are assembled on the board.

According to a further aspect, there is provided a chip-containing product comprising the above system assembled on a further board with at least one other product component.

According to a further aspect, there is provided a non-transitory computer-readable medium to store computer-readable code for fabrication of the above circuitry.

### BRIEF DESCRIPTION OF THE DRAWINGS

Embodiments of the present techniques will now be described by way of example only and with reference to the accompanying drawings, in which:

FIG. 1 schematically shows a block diagram of mitigator circuitry comprising clock throttler circuitry in accordance with the present techniques;

FIG. 2 schematically shows the mitigator circuitry of FIG. 1 in more detail in accordance with the present techniques;

FIG. 3 schematically shows the clock throttler circuitry of FIG. 1 in more detail in accordance with the present techniques;

FIG. 4 schematically shows example patterns in accordance with the present techniques;

FIG. 5 schematically shows an index target generator in accordance the present techniques;

FIG. 6a schematically show the operations of a first state machine of the mitigator circuitry in accordance with the present techniques;

FIG. 6b schematically show the operations of a second state machine of the mitigator circuitry in accordance with the present techniques;

FIG. 7 schematically shows a signal diagram for the mitigator circuitry of FIG. 1;

FIG. 8 schematically shows a simplified flow diagram of a method of operation of the clock throttler circuitry according to one implementation of the present techniques; and

FIG. 9 illustrates a system and a chip-containing product in accordance with the present techniques.

### DETAILED DESCRIPTION

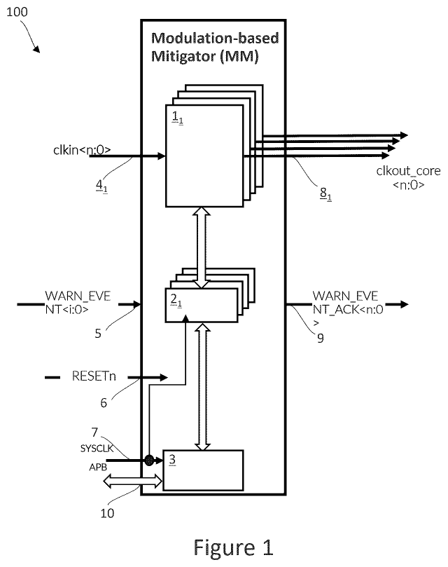

FIG. 1 schematically shows a block diagram of mitigator circuitry 100 comprising clock throttler circuitry 1 in accordance with the present techniques;

The mitigator circuitry 100 comprises one or more clock throttler circuits 1ₙ, one or more components comprising mitigation state machines 2₁ to control the one or more clock throttler circuits and storage circuitry 3, which in the illustrative example of FIG. 1 comprises a register bank 3 comprising a plurality of registers.

The mitigator circuitry 100 comprises various input and outputs to receive/provide signals (e.g. from external hardware and/or software components).

It will be appreciated that the term “signal” is non-limiting and may take any form to convey a message, operation or information to a component (hardware or software), where, for example, the signal may comprise one or more bits, a logic value (e.g. high or low), or a voltage value etc. In embodiments the signal may comprise a clock signal having a particular frequency and or level (e.g. voltage level).

Furthermore, the signals provided to a component (e.g. hardware or software) to control the operation thereof (E.g. to select a particular clock signal) or to change properties thereof (e.g. to cause the component to operate in a certain way) may be referred to as a “control signal.”

In FIG. 1, mitigator circuitry 100 comprises:
i. Input 4 to receive clock input signal (clkin<n:0>) having a plurality of clock pulses. Such a clock input signal may be from a phased locked loop clock (PLL) source and/or it may be a droop mitigated clock from a droop mitigation circuit;
ii. Input 5 to receive a configurable signal (WARN_EVENT<i:0>) to identify a warning event, such as an overcurrent even and/or overtemperature event;
iii. Input 6 to receive a reset signal (RESETn);
iv. Input 7 to receive a system clock signal (SYSCLK), which is provided to the one or more mitigation state machines 2₁ and storage 3; The system clock signal (SYSCLK) may be a relatively low frequency clock signal compared to clock input signal (clkin);
v. Output 8 to provide a clock output signal “clk_out_core <n:0> from each clock throttler circuit 1_{1,} and where each “clk_out_core <n:0> may be provided to a subsystem (e.g. a CPU, GPU, NPU etc.);
vi. Output 9 comprising a warning acknowledgement signal “WARN_EVENT_ACK,” which may be used for handshaking purposes;
vii. Interface 10, such as an Advanced Peripheral Bus (APB), which may be part of the Advanced Microcontroller Bus Architecture (AMBA) protocol family, although the claims are not limited in this respect.

The inputs/outputs and the operation of the mitigator circuitry 100 are

described in detail below. It will also be appreciated that additional inputs/outputs, or alternative inputs/outputs, may also be provided and the mitigator circuitry 100 is not limited to those depicted in FIG. 1.

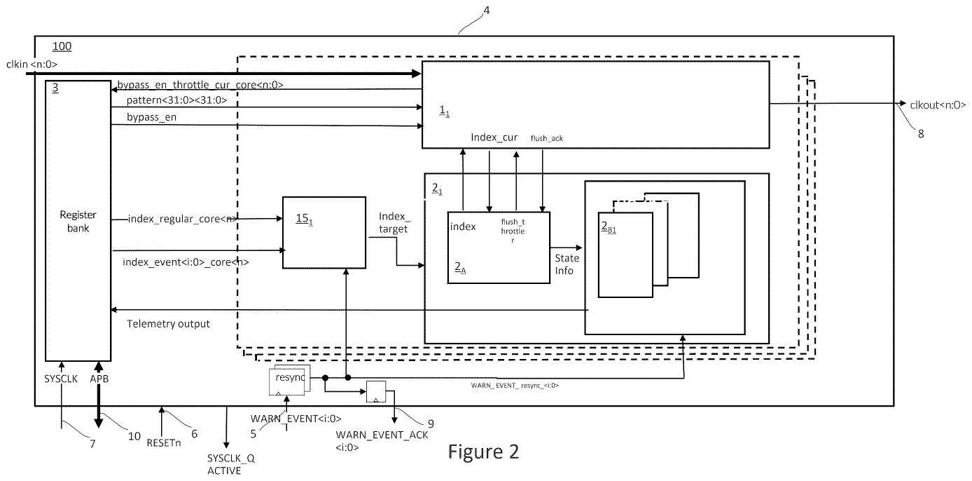

FIG. 2 schematically shows the mitigator circuitry 100 of FIG. 1 in more detail accordance with the present techniques, where a component comprising index target generator circuitry 15 is provided to generate an index target value (Index_target) for the mitigation state machine 2₁ responsive to signals from the register bank 3 and from external sources. The functionality of the index target generator circuitry 15 is described in greater detail below.

The register bank 3 receives the system clock signal (SYSCLK) 7 and external communications via the interface 10, where the registers of the register bank 3 may be accessed by, for example, firmware, via the interface 10. For example, the register bank 3 may receive one or more patterns of bits to be provided to the clock throttler circuit 1ₙ.

The register bank 3 provides various signals to the clock throttler circuit 1₁ and to the index target generator circuitry 15₁.

As an example, the register bank may provide one or more patterns of n-bits (e.g. 16-bit, 32-bit, 64-bit, 128-bit) to clock throttler circuit 1₁ using the “pattern<31:0><31:0>” signal, and may also provide a “bypass_en” signal to clock throttler circuit 1₁. As a further example, the register bank may provide “index_regular_core<n>” and “index_event<i:0>_core<n>” signals to the index target generator 15₁.

The register bank 3 may also receive various internal signals. As an example, the register bank 3 may receive a “bypass_en_cur_core<n:0>” signal from the clock throttler circuit 1₁.

The mitigation state machine 2₁ comprises a first state machine 2_{A} (depicted as an index state machine) which is to provide internal control signals (e.g. a pattern identifier “index” signal and “flush_throttler” signal) to the clock throttler circuit 1₁ to control the operation thereof, and one or more event state machines 2_{B} to generate telemetry data responsive to state information from the index state machine. The index state machine 2_{A} may receive one or more internal signals (e.g. “index_cur” and “flush_ack”) from the clock throttler circuit 1₁ and may receive the target index target value (Index_target) from the index target generator 15₁ and may update its states responsive to the received signals. The mitigation state machine 2₁ includes a plurality of event state machines 2_{B}, where an event state machine 2_{B} is provided for each event being monitored at the corresponding subsystem (E.g. at the subsystem receiving the clock output signal (clkout) from the clock throttler circuitry 1.

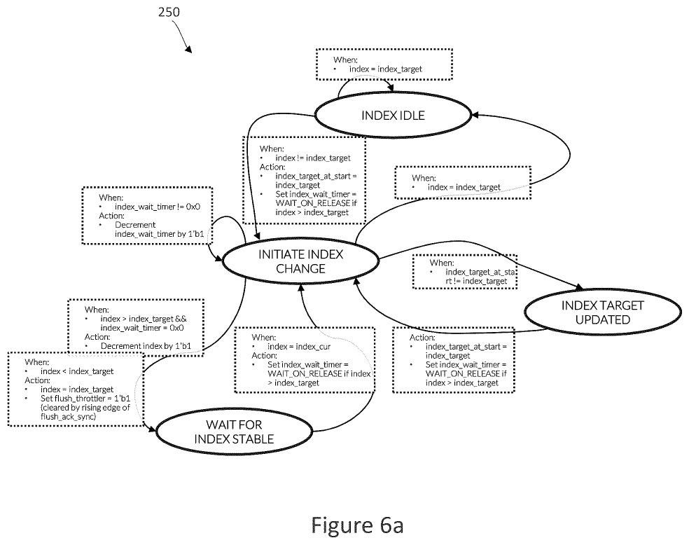

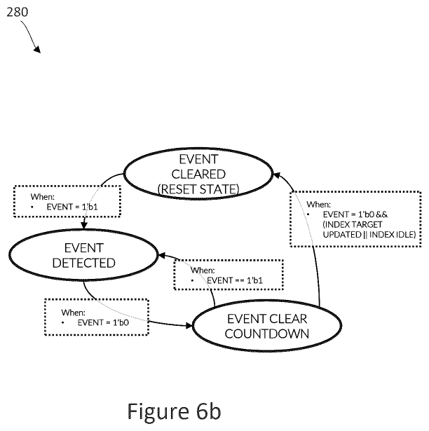

The operation of the first state machine is described in more detail at FIG. 6a below and the operation of the second state machine is described in more detail at FIG. 6b below.

In some embodiments the mitigator circuitry 100 may comprise synchronisation (“resync”) circuitry to synchronise external or internal signals to the system clock (SYSCLK) domain or to the clock input (clkin) domain.

The clock throttler circuitry 1ₙ receives a clock input signal (clkin) 4₁, where clock throttler circuitry 1₁ receives the clock input signal (clkin) 4₁ which comprises a plurality of pulses. Responsive to control signal, the clock throttler circuitry 1₁ passes or gates successive pulses of the clock input signal (clkin) 4₁ to provide the clock output signal (clkout) 8₁ comprising one or more pulses. For example, a pulse of the clock input signal (clkin) 4₁ may be passed when the control signal is high (or 1) such that the pulse of the clock input signal (clkin) 4₁ is passed and output in the clock output signal (clkout) 8₁. As a further example, a pulse of the clock input signal (clkin) 4₁ may be gated when the control signal is low (or 0) such that pulse of the clock input signal (clkin) is not output in the clock output signal (clkout) 8₁. Thus, gating pulses of the clock input signal (clkin) 4₁ means that the clock output signal (clkout) 8₁ will have fewer pulses than the clock input signal (clkin) 4₁. A clock output signal (clkout) 8₁ having fewer pulses than a corresponding clock input signal (clkin) is taken to be a throttled version of the clock input signal (clkin) 4₁ i.e. throttled a clock signal.

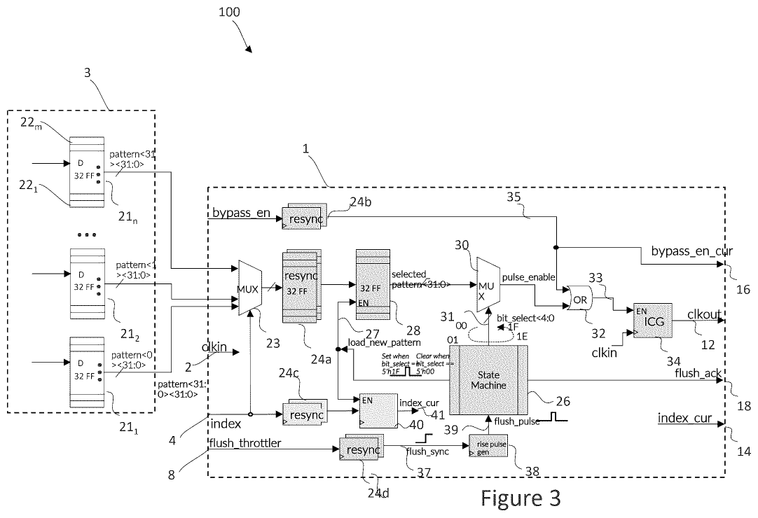

FIG. 3 is a schematic diagram a system 100 illustratively showing the clock throttler circuitry 1 in more detail. The system 100 also shows the register bank 3 in more detail, where in the present illustrative examples the register bank 3 comprises a plurality of n-bit registers 21₁ to 21ₙ, where each register is to store a plurality of bits 22₁ to 22ₘ. In the present illustrative example, each register is to store 32-bits, where each bit corresponds to a single bit of a 32-bit pattern as will be described in detail below.

As depicted in FIG. 3, first selection circuitry 23 (depicted as first multiplexer circuitry in FIG. 3), selects a pattern from one of the registers 21₁ to 21ₙ responsive to the index signal received from the mitigation state machine (not shown in FIG. 3). The pattern defines the throttle amount or rate (hereafter “throttle rate”) to be applied by the clock throttler circuit. The index signal may be received from the mitigation state machine responsive to an event that requires clock throttling for a particular subsystem (e.g. overcurrent event; overtemperature event).

The registers 21₁ to 21ₙ that store the respective patterns may be in a first clock domain (e.g. a relatively low frequency system clock (SYSCLK) domain) whereas at least some of the logic of the clock throttler circuitry 1 may be in a second clock domain (e.g. a relatively high frequency clock input (clkin) domain). Therefore, synchronisation circuitry 24a-d is provided to synchronise the input signals from the first clock domain to the second clock domain.

In FIG. 3, the selected pattern is provided from the first selection circuitry 23 to synchronisation circuitry 24a, where the synchronisation circuitry 24a comprises storage depicted as a register 24a to store the bits of the selected pattern therein. Then the selected pattern in the synchronisation circuitry 24a is passed to the selected pattern register 28 responsive to a first enable signal 27 (“load_new_pattern”) received at the selected pattern register 28 from the state machine 26.

Second selection circuitry 30 (depicted as second multiplexer circuitry in FIG. 3) selects, responsive to a particular value of “bit_select <4:0>” identifier signal 31, a particular bit of the pattern stored at the bit location/address in the selected pattern register 28 corresponding to the value of the “bit_select <4:0>” signal. The “bit_select <4:0>” signal 31 identifies a single bit location/address at the selected pattern register 28, where the state machine 26 provides bit_select <4:0> signals 31 in a successive or sequential manner. As an illustrative example, the second selection circuitry 30 will firstly select bit 0 of the pattern responsive to a first “bit_select <00>” signal, then select bit 1 of the stored pattern responsive to a next “bit_select <01>” signal, then select bit 2 of the stored pattern responsive to “bit_select <02>” signal and continue up to bit 31 responsive to bit_select <1F> signal, where all 32 bits are individually selected and successively passed to the logic gate 32 (i.e. responsive to an incremental sequence of bit_select <4:0> signals). Alternatively, the second selection circuitry 30 may firstly select bit 31 and then, in a decremental sequence responsive to “bit_select <4:0>” signals individually select all 32 bits and successively pass them to the OR gate 32 (i.e. responsive to an decremental sequence of bit_select <4:0> signals). Other sequences may also be envisaged.

The second selection circuitry 30 provides the bit selected responsive to a particular bit_select <4:0> signal 31 to the logic gate 32, and the individual bits are successively provided from the logic gate 32 as a pulse enable signal 33 to integrated clock gate (ICG) circuitry 34. The logic gate 32 is depicted as an OR gate, although the claims are not limited in this respect.

The ICG circuitry 34 receives the clock input signal (clkin), which comprises a plurality of pulses, and, responsive to applying the pulse enable signal 33, passes or gates successive pulses of the clock input signal (clkin) to provide the clock output (clkout) 12 dependent on the value of the pulse enable signal 33 applied at the ICG circuitry. For example, the ICG circuitry 34 may pass a pulse of the clock input signal when the applied pulse enable signal is high (or 1) such that the pulse of the clock input signal (clkin) is passed and output in the clock output signal (clkout) 12. As a further example, the ICG 34 may gate a pulse of the clock input signal (clkin) when the applied pulse enable signal is low (or 0) such that pulse of the clock input signal (clkin) is not output in the clock output signal (clkout). Thus, gating pulses of the clock input signal (clkin) means that the clock output signal (clkout) will have fewer pulses than the clock input signal (clkin). A clock output signal having fewer pulses than a corresponding clock input signal (clkin) is taken to be a throttled version of the clock input signal (clkin) i.e. throttled. The various patterns and signals may be used to control how the clock throttler circuitry 1ₙ throttles (i.e. the throttle rate) the clock output signal (clkout) 8₁ responsive to an event, such as an overcurrent event or an overtemperature event.

Thus, the clock throttler circuitry 1 can generate a throttled clock output signal (clkout) 8₁ which may be provided to a subsystem (e.g. CPU, GPU or NPU).

The logic gate 32 also receives bypass enable signal (bypass_en) 35 to bypass the first and second selection circuitry and prevent throttling. The bypass enable signal 35 may, when asserted (e.g. set to high (or 1)) cause the ICG 34 circuitry to pass all pulses of the clock input signal (clkin) irrespective of the pulse enable signal 33, which means that all pulses of the clock input signal (clkin) will be passed and provided as the clock output signal (clkout), so the clock output signal (clkout) will not be throttled. Such bypass functionality may be provided for a test sequence or responsive to a particular user requirement.

The logic gate 32 is optional, and in an alternative embodiment, the individual bits of the selected pattern may be passed from the second selection circuitry 30 directly to the ICG circuitry 34.

As the bits of the pattern selected responsive to “bit_select <4:0>” signals are provided as the enable signal for the ICG circuitry 34, the ICG circuitry 34 passes or gates the pulses of the clock input signal (clkin) responsive to applying the bits of the pattern selected responsive to “bit_select <4:0>” signals.

In embodiments, an event (or application or user) may require a new pattern to be applied rather than waiting for the state machine 26 to complete the cycle of “bit_select <4:0>” signals for a current pattern.

The first selection circuitry 23 may select the new pattern from one of the registers 21₁ to 21ₙ responsive to a new “index” signal received at input 4 identifying the new pattern and is provided to register 24a to store the bits of the selected new pattern.

To flush the current pattern from the selected pattern register a “flush_throttler” signal may be asserted (e.g. by a mitigation state machine not shown in FIG. 3). The “flush_throttler” signal is synchronised to the clock input signal (clkin) clock domain at synchronisation circuitry 24d and provided as a “flush_sync” signal 37 to rise pulse generation circuitry 38. Responsive to the “flush sync” signal the rise pulse generation circuitry generates a “flush_pulse” signal 39 and provides the “flush_pulse” signal 39 to the state machine 26.

Responsive to the “flush_pulse” signal 39 being asserted (e.g. for at least one clock cycle), the state machine 26 increments the value of the bit_select <4:0> signal to correspond to a location identifying a final bit of the selected pattern to be applied (e.g. bit 32 of a 32-bit pattern) and also provides a “load_new_pattern” pulse. The state machine 26 also asserts (e.g. sets to 1) a flush acknowledgement signal (flush_ack), and when the flush_sync signal is deasserted or cleared (e.g. when set to 0) the state machine 26 deasserts or clears (e.g. sets to 0) the flush acknowledgement signal (flush_ack).

Responsive to the “load_new_pattern” pulse being asserted, a new pattern is stored at the selected pattern register 28 and the state machine 26 then clears the “load_new_pattern” signal and restarts a new sequence of “bit_select <4:0>” signals to cause second selection circuitry 30 to select individual bits of the new pattern and pass them to the ICG 34 to be applied.

Thus, the “flush throttler” signal enables a current pattern being applied to be flushed from the selected pattern register 28 and replaced with a new pattern to be applied before the current pattern completes.

Furthermore, the clock throttler circuitry 1 may provide one or more signals about the operation of the clock throttler circuitry 1 to external circuitry or processes. For example, latch circuitry 40 receives the index signal also provided to the first selection circuitry 23 and, responsive to the “load_new_pattern” pulse, generates confirmation signal 41 (“index_cur”) to confirm the pattern that is currently being applied, where the confirmation signal (index_cur) 41 is output.

As further example, when the first and second selection circuitry of the clock throttler circuitry 1 is bypassed, a bypass currently enabled signal (“bypass_en_cur”) may be provided at output 16. As further example, the state machine 26 may also provide a flush acknowledgement signal (flush_ack) to the mitigation state machine.

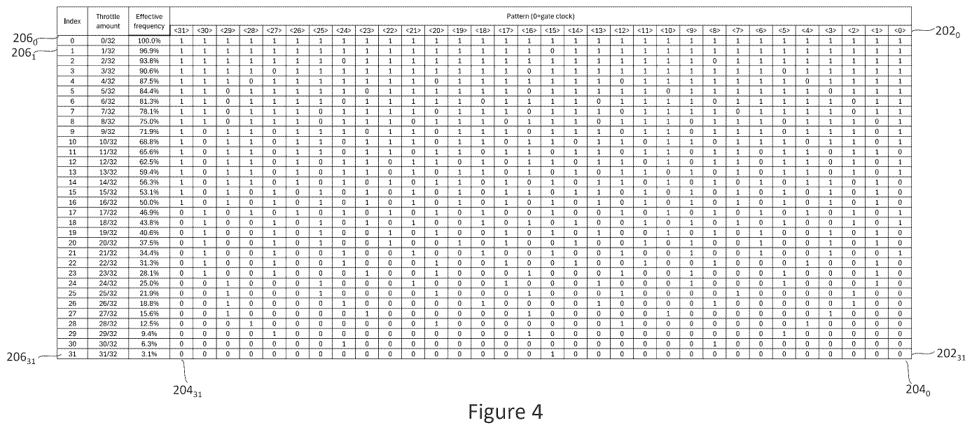

FIG. 4 schematically shows an example table 200 comprising 32 rows of patterns 202₀ to 202₃₁ in accordance with the present techniques.

The patterns in FIG. 4 are depicted as 32-bit patterns, each row having 32 bits 204₀ to 204₃₁. However, the claims are not limited in this respect and patterns of other sizes may be used and the claims are not limited in a particular size of the patterns. Furthermore, when a different sized pattern is used then the size/values of the various signals required to identify that pattern (e.g. the index <X:0> signal; index_cur<Y:0> signal) and/or the individual bits in that pattern (e.g. the bit_select <Z:0> signal) may also be changed accordingly.

As depicted in FIG. 4, each pattern may be identified by a corresponding pattern identifier, which in the present illustrative examples comprises an index value 206₀ to 206₃₁, where the index value may be specified in the pattern identifier (index <4:0>) signal received at the clock throttler circuitry 1.

Each bit of the respective patterns in the table of FIG. 4 has a value of 1 or 0, where when a bit having a value 1 is provided to an ICG and applied thereat, the ICG will pass a pulse of a clock signal (e.g. the clock input signal (clkin) depicted in FIG. 2a) and when a bit having a value 0 is provided to an ICG and applied thereat, the ICG will gate a pulse of a clock signal (e.g. the clock input signal (clkin) depicted in FIG. 2a), thereby throttling an effective frequency of the clock output signal.

Using the ICG to throttle the clock input signal does not affect the minimum width of the clock pulses or the minimum clock period of the pulses. Rather it is the effective frequency of the clock output signal that is throttled, where one or more pulses in the clock input signal may be gated responsive to bits in a pattern to reduce the number of corresponding pulses in the clock output signal over the length of the clock input signal to which the pattern was applied.

Thus throttling the effective frequency of a clock output signal rather than throttling the actual frequency of the clock output signal may address an event but may not impact/affect any timing-related signoff checks performed using that clock output signal.

Applying a 32-bit pattern of all 1s (i.e. the pattern at index 0 (206₀)) will result in the ICG passing all of the clock input signals responsive to pattern corresponding to index 0. Thus, applying pattern 0 will not have any throttle effect on the clock input signal.

Applying the 32-bit pattern at index 1 (206₁) will result in the ICG passing all but one of the clock input signals responsive to pattern at index 1 (206₁). Thus, applying the pattern at index 1 (206₁) will throttle the clock input signal to the ICG by approximately 3.1% to provide an effective frequency of 96.9% for the resulting clock output signal.

Similarly, applying the 32-bit pattern at index 31 (206₃₁) will result in the ICG gating all but one of the clock input signals responsive to pattern at index 31 (206₃₁). Thus, applying the pattern at index 31 (206₃₁) will throttle the clock input signal to the ICG by approximately 96.9% to provide an effective frequency of 3.1% for the resulting clock output signal.

Thus, gating a clock input signal responsive to a single bit of a 32 bit pattern will have a throttle rate of ˜3.1% on the effective frequency of the resulting clock output signal, and each additional bit will increase the throttle rate by ˜3.1% on the effective frequency of the resulting clock output signal.

Different patterns can be applied consecutively to achieve different throttle rates. For example, for the 32-bit pattern depicted in FIG. 4, applying index 1 followed by index 2 will provide a throttle rate of approximately 4.6% on the effective frequency of the resulting clock output signal.

It will be appreciated that the clock speed is not throttled when gating one or more pulses, rather it is the effective frequency that is throttled.

As depicted in FIG. 4 the zeros (0's) are distributed equally in each of the patterns. However the claims are not limited in this respect and different positions of the 1's and 0's can be used for each pattern. Taking the pattern at index 16 as an example, rather than having a sequence of 1, 0, 1, 0 . . . to provide a throttling rate of approximately 50% on the effective frequency, the pattern may be modified to have a pattern of sixteen bits each with a value of 1 followed by sixteen bits each with a value of 0. In a further example, a pattern of 100110100110 . . . may be used to provide the same throttle rate on the effective frequency (i.e. approximately 50%).

In an illustrative example, a particular pattern of 1s and 0's may, when applied, affect performance of the system (e.g. a pattern may ignite resonance frequencies in a power distribution network). Thus, the 1s and 0's in a particular pattern may be adjusted/programmed (e.g. via firmware) to avoid any negative effects as required.

Looking again at FIG. 3, the first selection circuitry 23 is to select a pattern along a particular row 202₀ to 202₃₁ responsive to the pattern identifier (index <4:0>) signal while the second selection circuitry 30 is to select individual bits along the columns 204₀ to 204₃₁ of the selected pattern responsive to the sequence of bit_select <4:0> signals from the state machine 26.

As set out above, the patterns are not limited to 32-bit patterns. When a 64-bit pattern is used, gating an clock input signal responsive to a single bit of a 64 bit pattern will have a throttle rate of ˜1.55% on the effective frequency of the resulting clock output signal, and each additional bit will increase the throttle rate on the effective frequency of the resulting clock output signal by ˜1.55%.

Therefore, the clock throttler circuitry can throttle the clock output signal to respond to one or more events, providing different levels of throttling as required.

As an illustrative example, the index provided to the clock throttler circuitry may be dependent the type of event, where when an overcurrent event is detected a first throttle rate (e.g. ˜15%) may be required so a pattern identifier (index <4:0>) signal identifies, via an index value therein, a pattern in a register of a first storage (e.g. first register bank) to be applied. In FIG. 4, the index value may identify the pattern corresponding to Index 5 which provides 15.5% throttle rate. Similarly, where an overtemperature event is detected then a second throttle rate (e.g. 10%) may be required, where the index value may identify the pattern corresponding to Index 3 which provides ˜9.4% throttle rate.

The index can also be provided based on the severity of the warning event. For example, an overtemperature warning at 85° C. may require a throttle rate of ˜10% (Index 3); an overtemperature warning at 90° C. may require a throttle rate of ˜15% (Index 5); an overtemperature warning at 95° C. may require a throttle rate of ˜20% (Index 7); and an overtemperature warning at 100° C. may require a throttle rate of ˜30% (Index 9).

The warning events may be received from a corresponding subsystem receiving the clock output signal from the clock throttler circuit, where a CPU may have one or more temperature sensors to generate the overtemperature warnings and a power management integrated circuit (PMIC) may provide the overcurrent warnings.

The mitigation state machine can then control the clock throttler circuitry 1 to provide a throttle rate dependent on the warning event, and when the warning event is cleared the mitigation state machine can control the throttling functionality to mitigate any adverse effects of reducing the throttle rate.

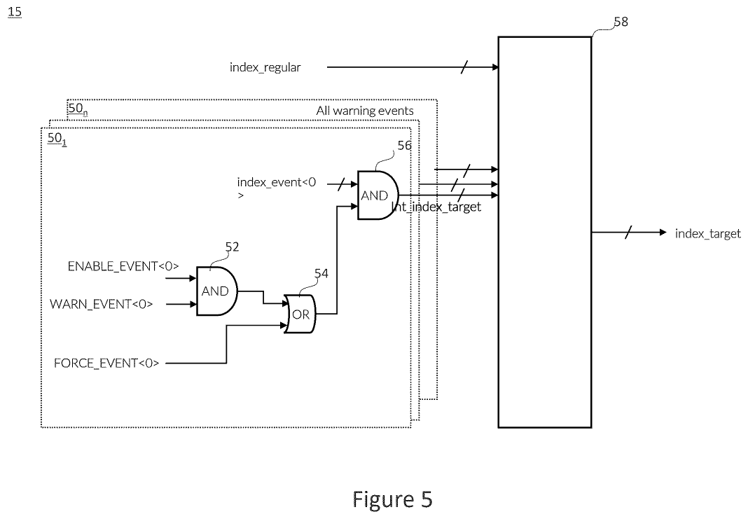

FIG. 5 illustratively shows an example embodiment of the index target generator 15 in accordance the present techniques.

The index target generator 15 comprises a plurality of intermediate index target generator circuits 50ₙ, where each intermediate index target generator circuit 50 is to generate an intermediate target (“int_index_target”) signal, to identify an index corresponding to a pattern which the clock throttler circuit is to apply to the ICG to throttle a clock output signal. Each intermediate index target generator circuit 50ₙ may be configured to generate the respective “int_index_target” signal responsive to a particular event (e.g. overcurrent, overtemperature etc.).

Each intermediate index target generator circuit 50ₙ comprises first logic gate 52 (depicted as an AND gate in FIG. 5), where an enable signal “ENABLE_EVENT<0>” is provided as a first input to the AND gate 52 and a warning event signal “WARN_EVENT <0>” identifying a detected event (e.g. at a corresponding subsystem) is provided as a second input to the AND gate 52. The enable signal, when deasserted or cleared (e.g. 0 or LOW) for an AND gate 52 of a particular intermediate index target generator circuit 50ₙ can be used to disable that particular intermediate index target generator circuit 50_{n.} The AND gate 52 is optional.

The output of the AND gate 52 is provided as a first input to a second logic gate 54 (depicted as an OR gate), where the OR gate 54 receives a throttler force signal “FORCE_EVENT<0>” as a second input thereto. The throttler force signal can force an event, such that when asserted (1 or High), the OR gate 54 will always output a 1 or a HIGH. The throttler force signal can be used for testing purposes. The OR gate 54 is optional.

The output of the OR gate 54 is provided as a first input to a third logic gate 56 (depicted as an AND gate), where the AND gate 56 receives an index event n-bit signal (index_event <0>) which is to identify an index to use for that particular event. The index_event <0> signal identifying the index may be provided by a state machine responsive to the detected event.

The AND gate 56 outputs the intermediate index target (int_index_target). When the output of the AND gate 56 is 0 or LOW then there is no warning, and no intermediate target index will be generated.

The index target generator 15 comprises a function block 58 to receive the intermediate index target signals from the one or more of the intermediate index target generator circuits 50ₙ, where the function block is configured to apply a function to generate the index_target signal which is provided to the mitigation state machine.

The function may be a MAX function, where the highest intermediate index target from the one or more generator circuits 50ₙ is selected as the index_target which is provided to the mitigation state machine or an ADD function where the intermediate index values of the one or more generator circuits 50ₙ are added together and the sum of the index values provided to the mitigation state machine.

As an example, a first index target generator circuit 50₁ may identify index 10 as the int_index_target responsive to an overcurrent event, whereas a second index target generator circuit 50₂ may identify index 15 as the int_index_target responsive to an overtemperature event, and applying the MAX function would result in index 15 selected as the index_target which is provided to the mitigation state machine.

As a further example, a first index target generator circuit 50₁ may identify index 6 as the int_index_target responsive to an overcurrent event, whereas a second index target generator circuit 50₂ may identify index 8 as the int_index_target responsive to an overtemperature event, and applying the ADD function would result in index 14 selected as the index_target which is provided to the mitigation state machine.

The function block 58 may also receive a default signal (“index_regular”) to indicate the value of index_target when there is no warning event detected.

As described above at FIG. 2, the mitigation state machine 2₁ comprises an index state machine which is to provide internal control signals (e.g. a pattern identifier “index” signal and “flush_throttler” signal) to the clock throttler circuit 1 to control the operation thereof, and an event state machine 2_{B} which is to provide telemetry data.

FIG. 6a schematically shows a state machine operation 250 for an index state machine in accordance with an embodiment of the present techniques.

The index state machine is to control the clock throttler circuit 1 to match the current index being applied with the target index identified in the index_target signal from the index target generator circuit.

In an IDLE state, where a current target is achieved, when the current index being applied does not match the target index identified by the index_target signal, then the index state machine sets a value “index_target_at_start” to the value of “index_target”, and then sets a timer “index_wait_timer” to a value WAIT_ON_RELEASE if the current index being applied is higher than the target index identified by the index_target signal. The timer index_wait_timer is a programmable timer, which provides for a gradual decrease from a higher current index to a lower target index.

The state is then changed to INITIATE INDEX CHANGE.

When, at the INITIATE INDEX CHANGE state, the current index being applied is lower than the target index identified by the index_target signal (i.e. when more throttling is required e.g. responsive to a warning event) then the “index” signal sent to the clock throttler circuit is set to the value of the index_target signal i.e. to identify the target pattern to be applied. The state machine could also initiate a flush if it's determined that the pattern identified by the index_target should be applied without waiting for the current pattern to complete.

Then the state changes to WAIT FOR INDEX STABLE.

When, at the INITIATE INDEX CHANGE state, the current index being applied is higher than the target index identified by the index_target signal (i.e. when less throttling is required e.g. responsive to a warning event being cleared) and when the “index_wait_timer” is zero, then the value of the “index” signal that was previously sent to the clock throttler circuit is decremented by 1, and the state changes to WAIT FOR INDEX STABLE.

When at the WAIT FOR INDEX STABLE STATE, and when the index=index_cur (i.e. the desired index is the current index), then the index state machine sets the timer “index_wait_timer” to the value WAIT_ON_RELEASE if the current index being applied is higher than the target index identified by the index_target signal).

The state is then changed to INITIATE INDEX CHANGE to operate as above. Such functionality means that when a lower throttle rate is required, the risk of any adverse effects occurring when returning to the lower throttle rate from a higher throttler rate after a warning error is cleared is reduced.

When, at INITIATE INDEX CHANGE state, the index being applied is the same as the target index (i.e. when the pattern that is being applied is the same as pattern identified by the target index), the state returns to the INDEX IDLE state.

While initiating a change in index at the clock control circuit, it is possible that that the target index is updated, e.g. because a new warning event occurs. Therefore, when at INITIATE INDEX CHANGE state, the index_target value does not equal the previously set “index_target_at_start” value, then the state machine changes state to INDEX TARGET UPDATED state, and updates the “index_target_at_start” value to be the new “index_target” value, and sets the index_wait_timer when the current index is higher than the new target index (i.e. when less throttling is required).

FIG. 6b shows a state machine operation 280 for an event state machine in accordance with the present techniques.

The mitigation state machine 2₁ includes a plurality of event state machines, where an event state machine may be provided for each event being monitored at a corresponding subsystem.

When an event (e.g. an overcurrent or overtemperature event) is detected when operating in the EVENT CLEARED (RESET STATE) state, the state machine transitions to EVENT DETECTED state.

When the event is cleared the state machine transitions to an EVENT CLEAR COUNTDOWN, where, as above, the clock throttler circuitry may ramp down the throttling rate, e.g. by decrementing the index value until the index_regular value is reached so a timer is set to measure how long the clock throttler circuit takes to return to operating in accordance with the index_regular (i.e. applying a pattern corresponding to the index_regular (e.g. Index 0 in FIG. 4).

When a further event is triggered when the event state machine is in the EVENT CLEAR COUNTDOWN state, then the event state machine transitions to the EVENT DETECTED state.

When no further event is detected and the index state machine is in the INDEX IDLE state (see FIG. 6a) then the event state machine transitions to the EVENT CLEARED (RESET STATE).

The event state machine provides telemetry data e.g. to the register bank, where it can be accessed by an application. The telemetry data provides information about the operation of the mitigator circuitry 100 and/or the corresponding subsystem. For example, determining how long the event state machine spends in the EVENT CLEARED (RESET STATE) to provide insight into the efficiency/performance of the patterns that are applied because, for example, when operating outside of the EVENT CLEARED (RESET STATE) the performance of the system may be degraded due to operating at a throttled effective frequency.

The telemetry information provided by an event state may include those listed at A-D below. For the purposes of this example, the event state machine is taken to be operating responsive to detection of overcurrent events:
A. New Events: how many new events occurred, e.g. if a first PMIC (or overcurrent) event is detected, then that first PMIC event is cleared, and a second PMIC event is detected after the first PMIC event is cleared.
B. Repeat Events: if a first PMIC event is detected, then that first PMIC event is cleared, but while in the EVENT CLEAR COUNT DOWN state a second PMIC event is detected.
C. Other Events: A PMIC event is detected when another event state machine (E.g. addressing an overtemperature event) is in the EVENT DETECTED state or EVENT CLEAR COUNTDOWN state.
D. Duration: the length of time the event state machine spent in the EVENT DETECTED state or EVENT CLEAR COUNTDOWN state

The telemetry information may be used to change the patterns. For example, when it's determined that the amount of events detected is more than expected the different pattern configurations (e.g. different bit positions of 1s and 0s within the respective patterns) could be applied to attempt to reduce the number of events.

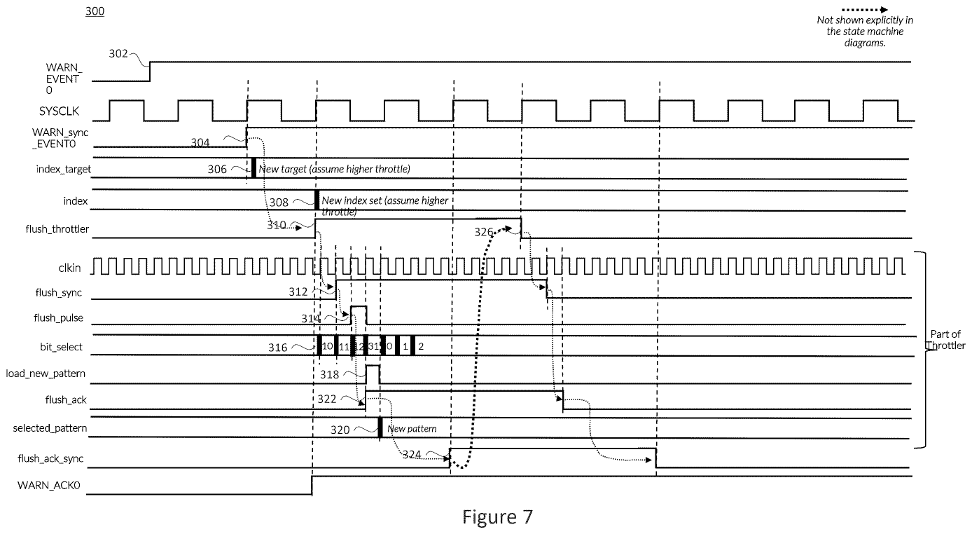

FIG. 7 schematically shows a signal diagram 300 for the mitigator circuitry 100.

As depicted, system clock (SYSCLK) may be a relatively low frequency clock signal compared to clock input signal (clkin).

In operation, when an event is detected, an asynchronous warning signal WARN_EVENT0 is asserted (302), and synchronised with the system clock, where a synchronised version of the warning signal (WARN_sync_EVENT0) is subsequently asserted (304) aligned with a pulse of the system clock.

The index_target is updated with a new value responsive to WARN_sync_EVENT0 (306). As depicted in FIG. 5, the target value is generated by combinatorial logic, so the value of index_target can be updated without having to wait for a clock edge. In the present illustrative example, the new target value requires a higher throttle rate than the current target. In the next SYSCLK cycle, the index is updated to the new target (308).

In the present illustrative example, the current pattern is required to be flushed before it fully completes its sequence, so a flush_throttler signal is asserted (310).

The clkin, flush_sync, flush_pulse, bit select, load_new_pattern, flush_ack and selected_pattern signals are provided to or generated by the clock throttler circuit.

As depicted, the clock input signal (clkin) is a relatively high frequency clock compared to the system clock (SYSCLK).

The flush_throttler signal is synchronised from the system clock (SYSCLK) domain to the clock input (clkin) domain, as signal flush_sync (312).

Responsive to the flush_sync signal, a flush_pulse signal is provided to the state machine in the clock throttler circuit (314).

Responsive to the flush_pulse signal, the state machine provides a “bit_select <4:0>” signal having a value corresponding to a location at the selected pattern register storing the last bit of the selected pattern (bit 31 of a 32-bit pattern) (316) and also asserts a “load_new_pattern” pulse (318).

Responsive to the “load_new_pattern” pulse being asserted (318), the selected pattern stored at the synchronisation circuitry is passed to the selected pattern register to be stored therein to be applied at the ICG.

A flush acknowledgement signal (flush_ack) is also asserted to confirm that the pattern corresponding to the current index has been flushed (322), and the flush_ack signal is synchronised to flush_ack_sync (324) used to deassert or clear the flush_throttler signal (326).

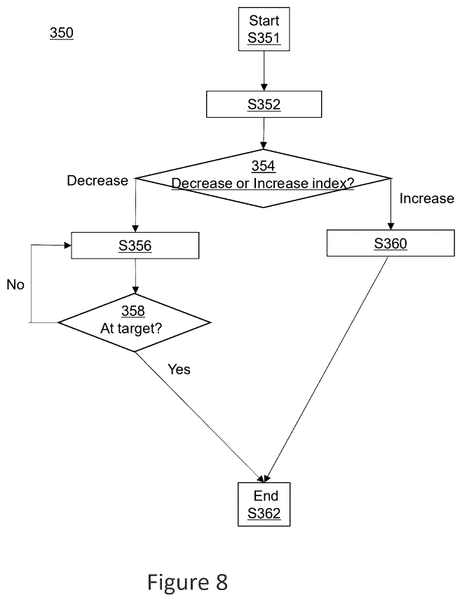

Turning now to FIG. 8, there is shown a simplified flow diagram of a method 350 of operation clock throttler circuitry according to one implementation of the present techniques.

An instance of the method starts at S351.

At S352 a target generator circuit generates a target index which identifies a pattern to be applied to control a throttle rate of a clock output signal. When an event is detected, a target generator circuit monitoring that event can generate a target index (index_target) identifying a pattern to be applied for that event. When no event is detected the target generator circuit monitoring that event can generate a default target index (index_regular) corresponding to a default pattern which the clock throttler circuit uses when no throttling is required (e.g. Index 0 where the clock output is not throttled). In embodiments, the default target index may correspond to a patter that, when applied, provides some level of throttling. Such functionality may be useful, for example, for a low priority core.

At S354 a first state machine determines, responsive to the target index, whether the current index (index) should be increased to meet the target index or whether the current index (index) should be decreased to meet the target index.

When, at S354 it's determined that the current index being applied should be decreased to the value of the index_target (e.g. index_regular due to a clearing of a warning event), the index state machine, at S356, decrements the index value by 1 in and provides the updated index value to the clock throttler circuit.

At S358, the index state machine determines whether or not the current index applied at the clock throttler circuit is at the target index (e.g. new warning event may have been detected resulting in higher target index from the target generator circuit).

When the current index is higher than the target index the flow returns to S356, and the index is decremented until the target index is reached. Therefore, when the current index being applied is higher than a target index, the index value applied at the clock throttler circuit can be decremented until the target index is reached.

Whilst it is possible to change directly from a relatively high index value (e.g. index 10) to a relatively low index (e.g. index 0), such a change may have adverse effects at the subsystem which receives the resulting clock output signal (e.g. overcurrent or overtemperature due to the sudden increase in the clock signal).

Therefore, ramping down the index (and the resulting ramping down of throttle rate of the resulting clock output signal) mitigates any adverse effects that might result from changing from a relatively high index to a relatively low index different levels throttle rates. Whilst the index is ramped down in steps of 1, the claims are not limited to a decremental step size of 1, and a higher step size may be used (E.g. 2, 3, 4 etc.) to decrement the index.

When, at S354 it's determined that the current index being applied should be increased to the value of the index_target (e.g. due to warning event such as an overcurrent and/or an overtemperature event), the index state machine, at S360, increases the index value to that of index_target and provides the updated index value to the clock throttler circuit.

The clock throttler circuit could be ramped up in various step sizes, but generally changing from a relatively low index value (e.g. index 0) to a relatively high index value (e.g. index 15) will have a higher mitigation effect on the detected event (e.g. overcurrent and/or overtemperature) compared to ramping up the throttle rate.

At S362, the method 350 ends.

Thus the present techniques provide mitigator circuitry which can be used to throttle a clock signal responsive to a detected event, and to control the amount of throttling when a new event occurs or when the detected event is cleared (or addressed). The throttled clock signal can be provided to an integrated circuit subsystem (e.g. E.g. central processor units (CPU), graphics processor units (GPU), neural processor units (NPU) etc.).

One or more clock throttler circuits may be provided in a data processer system, where such a data processor system may include one or more subsystems.

For example, a data processor unit may have multiple CPU tiles where one or more clock throttler circuits may be provided inside each CPU tile. The functionality can be used to independently control the clock signals supplied to each CPU tile or to each core within a CPU tile.

In an illustrative example, a CPU may comprise a first core running a thread at a high priority from a software perspective (high priority core) and another core running a thread at a lower priority (low priority core). Thus, a pattern of all 1's may be selected and applied to the clock signal provided to the high priority core and a pattern with one or more zeros may be selected and applied to the clock signal of the low priority core to throttle the effective frequency thereof. In this way the data processing system can use one or more clock throttler circuits to provide clock signals having different effective frequencies to different cores, for example, to generate less heat in the system.

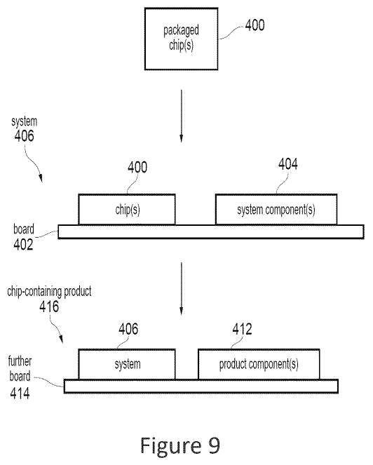

As shown in FIG. 9, one or more packaged chips 400, with the circuitry described above implemented on one chip or distributed over two or more of the chips, are manufactured by a semiconductor chip manufacturer. In some examples, the chip product 400 made by the semiconductor chip manufacturer may be provided as a semiconductor package which comprises a protective casing (e.g. made of metal, plastic, glass or ceramic) containing the semiconductor devices implementing the circuitry described above and connectors, such as lands, balls or pins, for connecting the semiconductor devices to an external environment. Where more than one chip 400 is provided, these could be provided as separate integrated circuits (provided as separate packages), or could be packaged by the semiconductor provider into a multi-chip semiconductor package (e.g. using an interposer, or by using three-dimensional integration to provide a multi-layer chip product comprising two or more vertically stacked integrated circuit layers).

In some examples, a collection of chiplets (i.e. small modular chips with particular functionality) may itself be referred to as a chip. A chiplet may be packaged individually in a semiconductor package and/or together with other chiplets into a multi-chiplet semiconductor package (e.g. using an interposer, or by using three-dimensional integration to provide a multi-layer chiplet product comprising two or more vertically stacked integrated circuit layers).

The one or more packaged chips 400 are assembled on a board 402 together with at least one system component 404 to provide a system 406. For example, the board may comprise a printed circuit board. The board substrate may be made of any of a variety of materials, e.g. plastic, glass, ceramic, or a flexible substrate material such as paper, plastic or textile material. The at least one system component 404 comprise one or more external components which are not part of the one or more packaged chip(s) 400. For example, the at least one system component 404 could include, for example, any one or more of the following: another packaged chip (e.g. provided by a different manufacturer or produced on a different process node), an interface module, a resistor, a capacitor, an inductor, a transformer, a diode, a transistor and/or a sensor.

A chip-containing product 416 is manufactured comprising the system 406 (including the board 402, the one or more chips 400 and the at least one system component 404) and one or more product components 412. The product components 412 comprise one or more further components which are not part of the system 406. As a non-exhaustive list of examples, the one or more product components 412 could include a user input/output device such as a keypad, touch screen, microphone, loudspeaker, display screen, haptic device, etc.; a wireless communication transmitter/receiver; a sensor; an actuator for actuating mechanical motion; a thermal control device; a further packaged chip; an interface module; a resistor; a capacitor; an inductor; a transformer; a diode; and/or a transistor. The system 406 and one or more product components 412 may be assembled on to a further board 414.

The board 402 or the further board 414 may be provided on or within a device housing or other structural support (e.g. a frame or blade) to provide a product which can be handled by a user and/or is intended for operational use by a person or company.

The system 406 or the chip-containing product 416 may be at least one of: an end-user product, a machine, a medical device, a computing or telecommunications infrastructure product, or an automation control system. For example, as a non-exhaustive list of examples, the chip-containing product could be any of the following: a telecommunications device, a mobile phone, a tablet, a laptop, a computer, a server (e.g. a rack server or blade server), an infrastructure device, networking equipment, a vehicle or other automotive product, industrial machinery, consumer device, smart card, credit card, smart glasses, avionics device, robotics device, camera, television, smart television, DVD players, set top box, wearable device, domestic appliance, smart meter, medical device, heating/lighting control device, sensor, and/or a control system for controlling public infrastructure equipment such as smart motorway or traffic lights.

As will be appreciated by one skilled in the art, the present technology may be embodied as a method, a circuit or a computer readable medium comprising data and imperatives to cause construction of a circuit. Accordingly, the present technique may take the form of an entirely hardware embodiment, an entirely software embodiment, or an embodiment combining software and hardware. Where the word “component” is used, it will be understood by one of ordinary skill in the art to refer to any portion of any of the above embodiments.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

In the present application, the words “configured to . . . ” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

In the present application, lists of features preceded with the phrase “at least one of” mean that any one or more of those features can be provided either individually or in combination. For example, “at least one of: [A], [B] and [C]” encompasses any of the following options: A alone (without B or C), B alone (without A or C), C alone (without A or B), A and B in combination (without C), A and C in combination (without B), B and C in combination (without A), or A, B and C in combination.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope of the invention as defined by the appended claims.

1. Circuitry for controlling a clock throttle circuit, the circuitry comprising:
a first component to:
receive a target index corresponding to a target level of throttle for a clock output signal at the clock throttle circuit;
determine a current index implemented at the clock throttle circuit, where the current index corresponds to a current level of throttle of the clock output signal;
provide, responsive to the determination, an index signal to cause the clock throttle circuit to throttle the clock output signal in accordance with the index signal.

2. The circuitry of claim 1, where the target level of throttle is less than the current level of throttle.

3. The circuitry of claim 2, where index signal is to cause the clock throttle circuit to decrease the current level of throttle to the target level over one or more levels.

4. The circuitry of claim 1, where the target level of throttle is greater than the current level of throttle.

5. The circuitry of claim 4, where index signal is to cause the clock throttle circuit to increase the current level of throttle to the target level.

6. The circuitry of claim 1, where the index corresponds to a pattern of bits to be applied at the clock throttler circuitry, where:
a bit having a first value is, when applied, to pass a pulse of a clock input signal as the clock output signal;
a bit having a second value is, when applied, to gate a pulse of a clock input signal as the clock output signal.

7. The circuitry of claim 6, where the first component is to provide a flush signal to cause the clock throttle circuit to flush the pattern before all bits of the pattern are applied to the clock input signal.

8. The circuitry of claim 1, where the first component comprises a first state machine.

9. The circuitry of claim 1, further comprising a second component, where the second component comprises one or more index target generator circuits, each index target generator circuit to generate an intermediate target index for a respective event.

10. The circuitry of claim 9, where a first index target generator circuit is to generate a first intermediate target index responsive to a first event and/or where a second index target generator circuit is to generate a second intermediate target index responsive to a second event.

11. The circuitry of claim 10, where the second component is to provide the target index responsive to the intermediate target indexes from the one or more index target generator circuits.

12. The circuitry of claim 11, where the second component is to apply a function to the intermediate target indexes from the one or more index target generator circuits to provide the target index.

13. The circuitry of claim 9, where the second component is to provide a default index when no event is detected.

14. The circuitry of claim 8, where the first component comprises a second state machine.

15. The circuitry of claim 8, where the second state machine is to generate telemetry information responsive to state information from the first state machine.

16. The circuitry of claim 1, where the clock output signal is provided to a subsystem.

17. A method for controlling a clock throttle circuit, the method performed by circuitry,
the method comprising:
receiving a target index corresponding to a target level of throttle for a clock output signal at the clock throttle circuit;
determining a current index implemented at the clock throttle circuit, where the current index corresponds to a current level of throttle of the clock output signal;
providing, responsive to the determination, an index signal to cause the clock throttle circuit to throttle the clock output signal in accordance with the index signal.

18. A system comprising:
the circuitry of claim 1, implemented in at least one packaged chip;
at least one system component; and
a board,
wherein the at least one packaged chip and the at least one system component are assembled on the board.

19. A chip-containing product comprising the system of claim 18 assembled on a further board with at least one other product component.

20. A non-transitory computer-readable medium to store computer-readable code for fabrication of the circuitry of claim 1.
